(19) United States
(12) Patent Application Publication
(10) Pub. No.: US 2004/0087121 A1
(43) Pub. Date: May 6, 2004

(54) Method of forming a nickel silicide region in a doped silicon-containing semiconductor area

(76) Inventors: Thorsten Kammler, Ottendorf-Okrilla (DE); Karsten Wieczorek, Dresden (DE); Markus Lenski, Dresden (DE)

Correspondence Address: J. Mike Amerson, Williams, Morgan & Amerson, P.C., Suite 1100, 10333 Richmond, Houston, TX, 77042, US

(21) Appl. No.: 10/440,656

(22) Filed: May 19, 2003

(30) Foreign Application Priority Data
Oct. 30, 2002 (DE) 102 50 611.6

(51) Int. Cl. H01L 21/336; H01L 21/8234; H01L 21/425

(52) U.S. Cl. 438/528; 438/530; 438/649; 438/197

(57) ABSTRACT

In highly sophisticated MOS transistors including nickel silicide portions for reducing the silicon sheet resistance, nickel silicide stingers may lead to short circuits between the drain and source region and the channel region, thereby significantly lowering production yield. By substantially amorphizing corresponding portions of the source and drain regions, the creation of clustered point defects may effectively be avoided during curing implantation induced damage, wherein a main diffusion path for nickel during the nickel silicide formation is interrupted. Thus, nickel silicide stingers may be significantly reduced or even completely avoided.

### BACKGROUND OF THE INVENTION

1. Field of the Invention

Generally, the present invention relates to the fabrication of integrated circuits, and, more particularly, to the formation of a metal silicide, such as a nickel silicide, on a silicon-containing doped semiconductor region to decrease a sheet resistance thereof.

2. Description of the Related Art

In modern ultra-high density integrated circuits, device features are steadily decreasing to enhance device performance and functionality of the circuitry. Shrinking the feature sizes, however, entails certain problems that may partially offset the advantages obtained by reducing the feature sizes. Generally, reducing the size of, for example, a gate electrode of a transistor element such as a MOS transistor, may lead to superior performance characteristics due to a decreased channel length of the transistor element, resulting in a higher drive current capability and enhanced switching speed. Upon decreasing the channel length of the transistor elements, however, the electrical resistance of conductive lines and contact regions, i.e., of regions that provide electrical contact with the periphery of the transistor elements, becomes a major issue since the cross-sectional area of these lines and contact regions is also reduced. The cross-sectional area, however, determines, in combination with the characteristics of the material comprising the conductive lines and contact regions, the effective electrical resistance thereof.

The majority of integrated circuits are based on silicon, that is, most of the circuit elements contain silicon regions, in crystalline, polycrystalline and amorphous form, doped and undoped, which act as conductive areas. An illustrative example in this context are the drain and source regions of a MOS transistor element. The source and drain regions are heavily doped, substantially-crystalline regions surrounded by a lightly inversely doped crystalline region, wherein a so-called channel region laterally separates the drain and source regions. A gate insulation layer, having formed thereon a gate electrode, usually formed of polycrystalline silicon, is located over the channel region and provides for a capacitive coupling of a control voltage applied to the gate electrode so as to create a conductive channel between the source and drain regions. Due to the shrinking dimensions of the transistor elements, the sheet resistance of the source and drain regions, as well as of the gate electrode, significantly increase and require appropriate counter measures in order to maintain the sheet resistance and, thus, transistor performance within specified tolerances. In many applications, especially in CMOS applications, it has therefore become standard practice to form a metal silicide in and on silicon-containing regions, such as the heavily doped source and drain regions and the polycrystalline gate electrode.

With reference to FIGS. 1a-1c, a typical conventional process flow for forming a metal silicide on corresponding portions of a MOS transistor element will now be described as an illustrative example for demonstrating the reduction of the sheet resistance of silicon.

FIG. 1a schematically shows a cross-sectional view of a transistor element 100, such as a MOS transistor, that is formed on a substrate 101 including a silicon-containing active region 102. The active region 102 is enclosed by an isolation structure 103, which in the present example is provided in the form of a shallow trench isolation usually used for sophisticated integrated circuits. Heavily doped source and drain regions 104, including extension regions 105 that usually comprise a dopant concentration less than the heavily doped regions 104, are formed in the active region 102. The source and drain regions 104, including the extension regions 105, are laterally separated by a channel region 106. A gate insulation layer 107 electrically and physically isolates a gate electrode 108 from the underlying channel region 106. Spacer elements 109 are formed as sidewalls of the gate electrode 108. A refractory metal layer 110 is formed over the transistor element 100 with a thickness required for the further processing in forming metal silicide portions on the gate electrode 108 and the source and drain regions 104.

A typical conventional process flow for forming the transistor element 100, as shown in FIG. 1a, may include the following steps. After defining the active region 102 by forming the shallow trench isolations 103 by means of advanced photolithography and etch techniques, well-established and well-known implantation steps are carried out to create a desired dopant profile in the active region 102 and the channel region 106.

Subsequently, the gate insulation layer 107 and the gate electrode 108 are formed by sophisticated deposition, photolithography and anisotropic etch techniques to substantially obtain a design gate length, which is the horizontal extension of the gate electrode 108 in FIG. 1a, i.e., in the plane of the drawing of FIG. 1a. Thereafter, a first implant sequence may be carried out to form the extension regions 105 wherein, depending on design requirements, additional so-called halo implants may be performed.

The spacer elements 109 are then formed by depositing a dielectric material, such as silicon dioxide and/or silicon nitride, and patterning the dielectric material by an anisotropic etch process. Thereafter, a further implant process may be carried out to form the heavily doped source and drain regions 104. Subsequently, the refractory metal layer 110 is deposited on the transistor element 100 by, for example, a chemical vapor deposition (CVD) or physical vapor deposition (PVD) process. Preferably, a refractory metal, such as titanium, cobalt, nickel and the like, is used for the metal layer 110. It turns out, however, that the characteristics of the various refractory metals during the formation of a metal silicide and afterwards in the form of a metal silicide significantly differ from each other. Consequently, selecting an appropriate refractory metal depends on further design parameters of the transistor element 100 as well as on process requirements of the following processes.

For instance, titanium is frequently used for forming a metal silicide on the respective silicon-containing portions wherein, however, the electrical properties of the resulting titanium silicide layer strongly depend on the dimensions of the transistor element 100. Titanium silicide tends to agglomerate at grain boundaries of polysilicon and therefore may increase the total electrical resistance of the gate electrode, wherein this effect is pronounced with decreasing feature sizes so that the employment of titanium may not be acceptable for transistor elements having a gate length of 0.5 micrometers and less.

For circuit elements having feature sizes of this order of magnitude, cobalt is preferably used as a refractory metal, since cobalt does not substantially exhibit a tendency for blocking grain boundaries of the polysilicon. Although cobalt may successfully be used for feature sizes down to 0.2 micrometers, a further reduction of the feature size may require a metal silicide exhibiting a significantly lower sheet resistance than cobalt silicide for the following reason. In a typical CMOS process flow, the metal silicide is formed on the gate electrode 108 and the drain and source regions 104 simultaneously in a so-called self-aligned process. This process flow requires that, for reduced feature sizes, a vertical extension or depth (with respect to FIG. 1a) of the drain and source regions 104 into the active region 102 needs to also be reduced in order to suppress so-called short channel effects. Consequently, a vertical extension or depth of a metal silicide region formed in and on the drain and source region 104 is limited by the requirement for a shallow P-N junction.

Therefore, for highly sophisticated transistor elements, nickel is increasingly considered as an appropriate substitute for cobalt as nickel silicide (NiSi monosilicide) shows a significantly lower sheet resistance than cobalt disilicide. In the following, it is therefore assumed that the refractory metal layer 110 is substantially comprised of nickel.

After deposition of the nickel layer 110, a heat treatment is carried out to initiate a chemical reaction between the nickel atoms and the silicon atoms in those areas of the source and drain regions 104 and the gate electrode 108 that are in contact with the nickel. For example, a rapid thermal anneal cycle may be carried out with a temperature in the range of approximately 400° C.-600° C. and for a time period of approximately 30-90 seconds. During the heat treatment, silicon and nickel atoms diffuse and combine to form nickel silicide. Thereafter, non-reacted nickel may be removed by a selective wet etch process.

FIG. 1b schematically shows the transistor element 100 with correspondingly formed nickel silicide layers 111 in the source and drain regions 104 and a nickel silicide layer 112 formed in the gate electrode 108. Respective thicknesses 111a and 112a of the nickel silicide layers 111, 112 may be adjusted by process parameters, such as a thickness of the initial refractory metal layer 110 and/or the specified conditions during the heat treatment. It should be noted that although the thicknesses 111a and 112a may differ from each other, they are nevertheless correlated and the differences thereof may be caused by a different diffusion behavior of heavily doped polysilicon in the gate electrode 108 and heavily doped crystalline silicon in the drain and source regions 104. Moreover, as pointed out above, a maximum value for the thickness 11a is restricted by the required depth of the P-N junction formed by the heavily doped source and drain regions 104 and the “lightly” doped extension regions 105 in the active region 102.

For the transistor element 100 shown in FIGS. 1a and 1b, a corresponding process flow may also be applied in conjunction with a refractory metal other than nickel, depending on device dimensions. When used with nickel, it turns out that, in combination with extremely scaled transistors having a gate length of 0.2 micrometers and less, a serious reduction of production yield may be observed.

FIG. 1c schematically shows a typical example for a device failure leading to a significantly reduced production yield. In FIG. 1c, the transistor element 100 additionally includes nickel silicide extensions 115, which may also be referred to herein as stingers, extending from the metal silicide regions 111 into the extension regions 105 and possibly into the channel region 106, thereby causing a short circuit of the P-N junction and thus preventing correct transistor function or at least significantly reducing transistor performance.

Since extremely scaled transistor elements required for high-end integrated circuits and future device generations necessitate the formation of highly conductive metal silicide regions, such as the regions 111, nickel may most likely be a preferred candidate as a refractory metal due to the superior sheet resistance compared to other refractory metal silicides. Therefore, a need exists for an improved technique for forming a highly conductive nickel silicide on a silicon-containing semiconductor region without unduly restricting production yield.

### SUMMARY OF THE INVENTION

The present invention is based on the finding that the formation of so-called metal stingers, such as nickel silicide extensions, extending from metal silicide regions formed in doped crystalline semiconductor regions, such as the source and drain regions, into the surrounding active region, for example into an active transistor region or a channel region of a field effect transistor, may effectively be reduced by significantly reducing the number of crystalline defects created during heavily doping a silicon-containing semiconductor region. As will be explained in more detail below, it is believed that the accumulation of crystalline defects caused by implantation and subsequent annealing leads to an enhanced nickel diffusion and thus to the formation of nickel silicide stingers.

Therefore, according to one illustrative embodiment of the present invention, a method of forming a silicide region in a doped silicon-containing semiconductor region comprises implanting inert ions into the silicon-containing semiconductor region to substantially amorphize a portion thereof. The substantially amorphous portion of the silicon-containing semiconductor region is doped, at least partially, and the substrate is heat treated to substantially recrystallize the substantially amorphous portion. A refractory metal is deposited on a part of the silicon-containing semiconductor region and the substrate is heat treated to initiate the metal silicide formation, wherein an intensified metal diffusion caused by crystal damage is reduced.

According to still another illustrative embodiment of the present invention, a method of forming a nickel silicide in a doped semiconductor region comprises implanting inert ions into the silicon-containing semiconductor region to substantially amorphize a portion thereof. The substantially amorphous portion of the silicon-containing semiconductor region is doped, at least partially, and the substrate is heat treated to substantially recrystallize the substantially amorphous portion. Then, a nickel layer is deposited on a part of the silicon-containing semiconductor region and a chemical reaction is initiated between nickel and silicon to form the nickel silicide layer, wherein an increased nickel silicide formation at clustered crystal defects in the recrystallized portion is reduced.

According to yet a further illustrative embodiment of the present invention, a method of forming a field effect transistor in accordance with a specified thermal budget comprises providing a substrate having formed thereon a silicon-containing semiconductor region with a gate insulation layer formed on the semiconductor region and a gate electrode located above the gate insulation layer. A portion of the silicon-containing semiconductor region is substantially amorphized and dopants are implanted into the semiconductor region to form doped source and drain regions. A heat treatment is carried out in accordance with a specified thermal budget to substantially recrystallize the portion and a nickel layer is deposited over a part of the semiconductor region. Then, a chemical reaction is initiated between the nickel layer and silicon to form nickel silicide layers in the source and drain regions, wherein a reduced number of agglomerated crystal defects reduces the formation of nickel silicide extensions.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a conventional transistor element during various stages of the manufacturing process;

FIGS. 2a-2c show a typical process flow for forming a field effect transistor that may lead to an increased device failure rate owing to nickel silicide stingers; and

FIGS. 3a-3e schematically show cross-sectional views of a field effect transistor formed in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

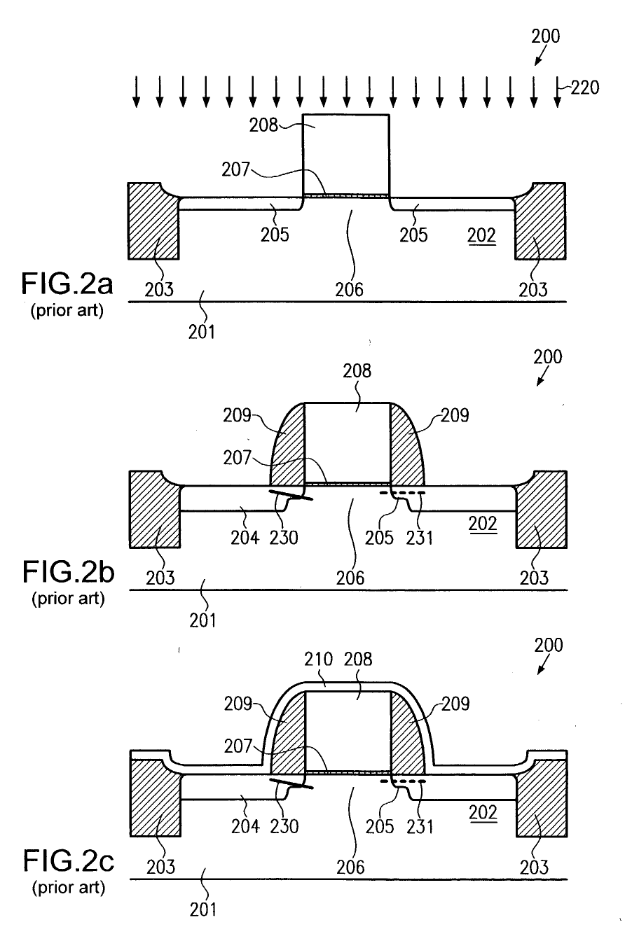

As previously mentioned, it is believed that crystal defects prevailing in a substantially crystalline semiconductor region, for example in source and drain regions of a field effect transistor, are the main reason for an undesired nickel diffusion during the nickel silicide formation and may lead to the formation of extensions or stingers. A typical process flow for forming a nickel silicide layer in a doped crystalline silicon region will now be discussed with reference to FIGS. 2a-2c with a field effect transistor element as an example semiconductor device.

FIG. 2a schematically shows a field effect transistor 200 in an early manufacturing stage, including a substrate 201 having formed thereon an active region 202 enclosed by shallow trench isolation 203. A gate insulation layer 207 separates a gate electrode 208 from a channel region 206. Lightly doped drain and source regions or extension regions 205 are formed in the active region 202 by an ion implantation process indicated by 220.

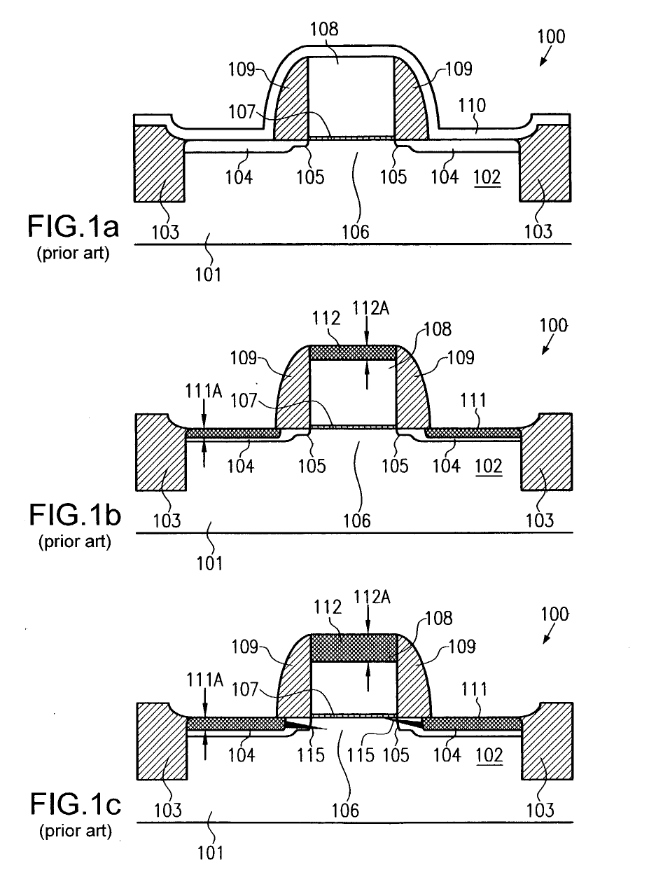

A process flow for forming the field effect transistor 200 as shown in FIG. 2a may comprise substantially the same process steps as already described with reference to FIG. 1a. It should be noted, however, that especially for extremely scaled transistor elements even the so-called “lightly doped” regions require a relatively high dopant concentration to provide for the necessary high conductivity so that a relatively high dose is used during the implantation 220, causing severe crystal damage in the active region 202. Moreover, as is well known, a heat treatment is necessary after an implantation cycle to activate the dopants and to cure the crystal damage. However, elevated temperatures lead to diffusion of dopants and other impurities, desired and undesired, thereby “blurring” boundaries between adjacent materials and regions and possibly inadvertently affecting the device characteristics. Therefore, very strict specifications regarding the duration and the temperatures employed in any heat treatments during the formation of the transistor element 200 have to be met so as to ensure proper operation of the device for a specified lifetime. These specifications regarding the temperature and duration of heat treatments are specified as a so-called “thermal budget” which determines, for example, the temperature and duration of anneal cycles required for activating dopants and curing crystal damage. In sophisticated transistor devices, however, small transistor dimensions requiring well-defined dopant profiles and severe crystal damage caused by high implantation doses are discrepant requirements and may not be satisfactorily met at the same time. Thus, the specified thermal budget may require reduced anneal temperatures and/or cycle times, leaving crystal defects, for the benefit of a reduced diffusion of dopants.

FIG. 2b schematically shows the field effect transistor 200 in an advanced manufacturing stage. Sidewall spacers 209 are formed on sidewalls of the gate electrode 208, and heavily doped source and drain regions 204 including the extension regions 205 are formed in the active region 202. The sidewall spacers 209 may be formed after the implantation 220 and prior to a second implantation for forming the heavily doped drain and source regions 204 so as to achieve the required lateral and vertical dopant profile. Thereafter, as explained above, a heat treatment, such as a rapid thermal anneal cycle, is carried out to activate the dopants and to cure the severe crystal damage caused by the two implantation steps. Upon annealing the field effect transistor 200, most of the portions including a damaged crystalline structure are recrystallized wherein, however, due to the necessary high dose of dopant atoms, the anneal temperature and/or time would have to be sufficiently high or long, respectively, to substantially completely recrystallize the source and drain regions 204 and especially the extension regions 205 below the sidewall spacers 209. Owing to the extremely reduced dimensions of highly sophisticated circuit elements, it turns out that a substantially complete recrystallization may not be accomplished without unduly promoting diffusion of the dopants, thereby significantly affecting the transistor characteristics.

It has been recognized that crystalline defects may agglomerate upon annealing the field effect transistor element 200 in accordance with an acceptable thermal budget, so that highly localized and clustered point defects are generated, as indicated by reference numerals 230 and 231. Although the reasons are not quite fully understood, it is presently believed that these localized and clustered or line-like point defects may act as a diffusion path for nickel during the formation of nickel silicide as will be described with reference to FIG. 2c.

In FIG. 2c, the field effect transistor 200 comprises a nickel layer 210 having a thickness that is appropriately selected to allow the formation of a nickel silicide region exhibiting a suitable thickness. Regarding the deposition of the nickel layer 210, the same criteria given with reference to FIGS. 1a-1c also apply in this case. Upon heat treating the field effect transistor 200, nickel and silicon diffuse to form nickel silicide, wherein the defects 230, 231 promote the nickel silicide formation and may lead to nickel silicide extensions, as for example shown in FIG. 1c, which may form a short between the extension regions 205 and the channel region 206 and/or may significantly affect transistor characteristics, for example, by influencing an electric field prevailing at the gate edges during transistor operation.

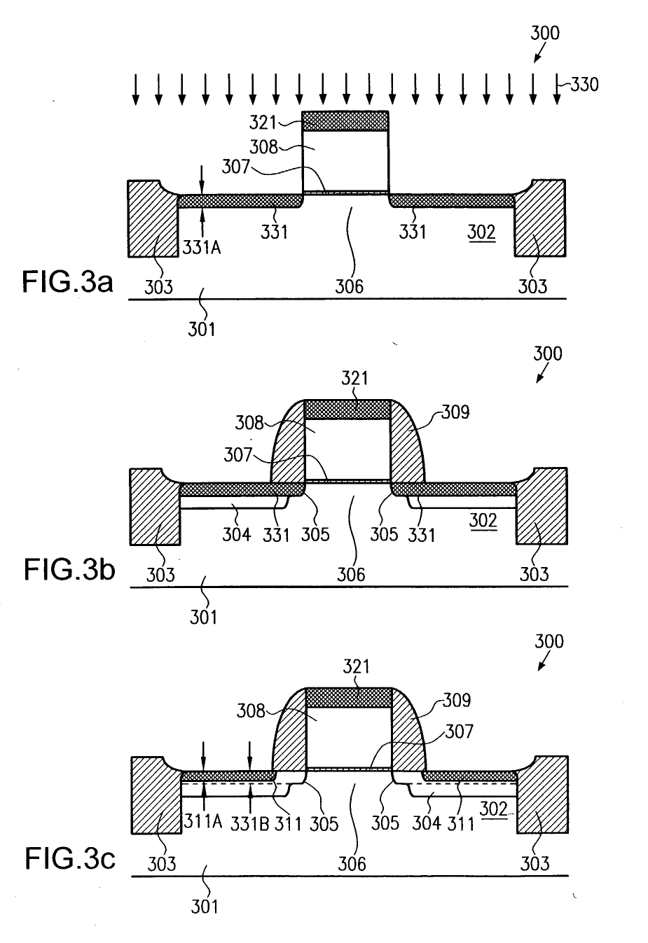

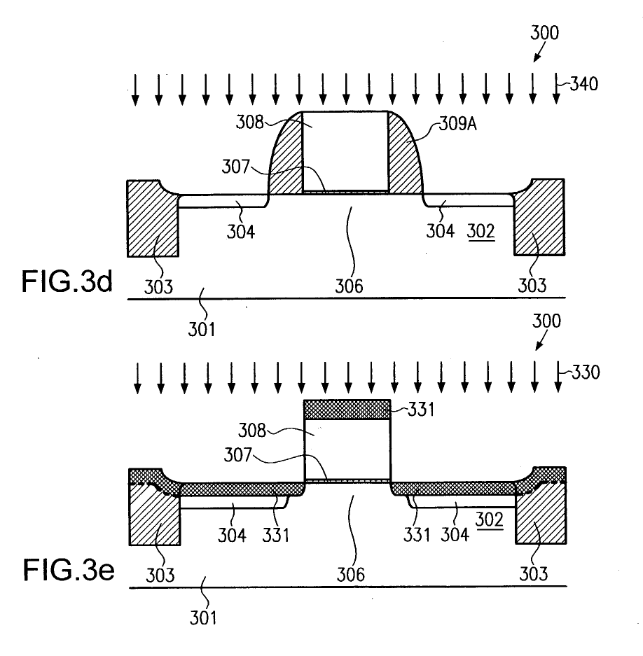

Based on this finding, with reference to FIGS. 3a-3e, illustrative embodiments of the present invention will now be described in which the formation of nickel silicide stingers are substantially eliminated or at least significantly reduced.

In FIG. 3a, a field effect transistor 300, such as a P-channel transistor or an N-channel transistor, includes a substrate 301, for example, a silicon substrate or an insulating substrate, such as commonly used for the silicon on insulator (SOI) technique, with an active region 302 enclosed by shallow trench isolations 303. A gate insulation layer 307 having formed thereon a gate electrode 308, typically formed of polysilicon (in other embodiments any appropriate gate electrode material may be used), provides electrical insulation of the gate electrode 308 from an underlying channel region 306. Substantially amorphized regions 331 are formed in a portion of the active region 302 not covered by the gate electrode 308 and on top of the gate electrode 308. A thickness or depth of the substantially amorphized regions 331 in the active region 302 is indicated by 331a.

A typical process flow for forming the field effect transistor 300 as shown in FIG. 3a may comprise the following steps. Forming the transistor structure 300 as shown may involve substantially the same steps as already described with reference to FIGS. 1a and 2a, except for the formation of the substantially amorphized regions 331. To this end, an ion implantation, indicated by reference sign 330, is performed in such a way that the unshielded portion of the active region 302 is substantially amorphized by ion bombardment within the specified thickness or depth 331a. In one embodiment, heavy inert ions are employed, such as xenon ions, to produce severe lattice damage without unduly penetrating the crystalline structure of the active region 302. The crystalline damage caused by ion bombardment depends on the mass of the ions, the acceleration voltage thereof and the dose and the duration of the bombardment and on the temperature of the substrate 301. Since a relatively high dose is required to sufficiently amorphize the crystalline structure of the active region 302, inert ions, i.e., ions that have merely a slight influence on the electrical characteristics of the completed field effect transistor 300, may be employed. In this context, the term “inert ion” is thus to be understood as an ion that may be incorporated into the crystalline structure after recrystallization without substantially affecting or only slightly affecting the electrical characteristics as well as the behavior during the further processing of the field effect transistor 300. Viable candidates for inert ions are, for example, noble gases such as xenon, argon, and the like, and, for example, materials having the same valency as silicon, such as the elements of the forth group of the periodic system. For example, germanium may also be considered as an inert implantation material, as germanium may not affect the type of conductivity of the surrounding doped silicon structure, although a heavy germanium concentration may lead to a variation of other physical properties, such as a reduction of the band gap energy. In certain cases, this property may advantageously be used in order to appropriately adjust the band gap energy for specific applications.

In one embodiment, xenon ions are employed at a dose of approximately 10¹⁴-10¹⁶ atoms/cm² with an energy in the range of approximately 20-180 keV. A temperature of the substrate is maintained within a range of approximately 200-500° C. during these implant processes. This leads to a substantial amorphization of the regions 331 in the active region 302 with a value for the thickness 331a in the range of approximately 50-200 nanometers. A substantially amorphized region may be more efficiently recrystallized without requiring as high a temperature and/or as long an anneal time as required for curing crystal damage caused by conventional implantations for forming extension regions and source and drain regions. However, in some embodiments, it may nevertheless be advantageous not to amorphize the source and drain regions in their entirety, but to tailor the thickness 331a with respect to a depth of a nickel silicide region to be formed, since recrystallization of the regions 331 having a reduced depth may additionally relax constraints on the thermal budget and may facilitate the amorphization implant process. Thus, the implantation parameters may be selected so that the thickness 331a substantially corresponds to a thickness of the nickel silicide regions to be formed.

In other embodiments, the substrate 301 may be tilted with respect to a direction of incidence of the ions 330, which is shown to be substantially vertically in FIG. 3a, so as to obtain a certain degree of amorphization below the gate insulation layer 307. This may be advantageous when any tilted implantations are carried out during formation of the lateral dopant profile in the active region 302. For example, highly sophisticated transistor elements may require a so-called halo implantation, wherein, in certain cases, an implantation under a tilt angle is needed. To achieve a desired profile of the substantially amorphized regions 331, the implantation 330 may be performed in several steps with differing tilt angles or may be performed as a single step implantation with or without gradually or step-wise altering the tilt angle.

After completion of the implantation 330, the process sequence is continued as, for example, described with reference to FIGS. 2a-2b and 1a-1b. That is, an implantation is carried out to form extension regions, followed by spacer formation and a subsequent implantation step for forming heavily doped source and drain regions.

FIG. 3b schematically shows the field effect transistor 300 after completion of this process sequence. The transistor 300 comprises heavily doped source and drain regions 304 including extension regions 305 and sidewall spacers 309.

Thereafter, a heat treatment, such as a rapid thermal anneal process, is carried out to substantially recrystallize the regions 331, wherein process parameters such as temperature and duration of the heat treatment are selected so as to meet the requirements of the specified thermal budget. For example, for a sophisticated CMOS sub-0.13 μm technology, an anneal temperature in the range of approximately 600-1200° C. and an anneal interval in the range of approximately 1-90 seconds may be used. As previously noted, recrystallization of a substantially completely amorphized region requires a reduced temperature and/or duration than recrystallization of damaged crystalline regions generated by a typical ion bombardment used for forming the extension regions 305 and the drain and source regions 304. Thus, substantially no clustered point defects within the substantially amorphized regions 331 will remain after curing compared to the conventional process flow, so that the generation of possible “nucleation” sites for silicide stingers, as shown in FIG. 1c, is substantially avoided or at least significantly reduced.

FIG. 3c schematically shows the field effect transistor 300 after recrystallization of the regions 331 and after formation of nickel silicide regions 311 in the source and drain regions 304 (and in the gate electrode 308) with a thickness 311a. The formation of the nickel silicide regions 311 may include the deposition of a nickel layer with a predefined thickness and a subsequent anneal cycle to convert nickel and silicon into nickel silicide (nickel monosilicide) with a required depth. Nickel silicide shows excellent characteristics in view of electric conductivity but is, however, thermally unstable at temperatures above approximately 400° C. and may readily further react with silicon to produce nickel disilicide (NiSi₂). Since the further reaction of nickel silicide into nickel disilicide consumes silicon and thus increases the thickness 311a, in some embodiments, the thickness of the substantially amorphized regions 331, indicated by 331b, may be selected so as to provide a certain margin for a further increase of the thickness 311a owing to a certain degree of conversion of nickel silicide into nickel disilicide during the further processing of the field effect transistor 300. In other embodiments, the substantially amorphized regions 331 may substantially completely fill the drain and source regions 304.

In a further embodiment, the implantation 330 shown in FIG. 3a may be carried out after performing the dopant implantation for defining the extension regions 305, thereby allowing the employment of well-established implantation parameters as in a conventional process flow as the amorphization does not need to be taken into account for defining the extension regions 305. That is, implanting ions into an amorphized region usually requires a different parameter selection than implantation into a crystalline region.

With reference to FIGS. 3d and 3e, a further embodiment of the present invention will be described. Components and parts already denoted and described with reference to FIGS. 3a-3c are indicated by the same numerals and a description thereof is omitted. In FIG. 3d, the field effect transistor 300 comprises sidewall spacers 309a formed on the sidewalls of the gate electrode 308, wherein these sidewall spacers 309a are considered as “disposable” sidewall spacers and are used as an implantation mask for an implantation 340 for defining the heavily doped source and drain regions 304.

FIG. 3e schematically shows the field effect transistor 300 after removal of the disposable sidewall spacers 309a and during the implantation 330 for forming the substantially amorphized regions 331. For carrying out the implantation 330 depicted in FIG. 3e, the same criteria apply as already pointed out with reference to FIG. 3a. Since the implantation 340 for defining the heavily doped source and drain regions 304 is carried out by using the disposable sidewall spacers 309a, substantially no crystal damage is generated in the vicinity of the gate electrode 308. Subsequently, further processing may be continued by implanting ions for forming the extension regions 305 (not shown in FIG. 3e) and forming sidewall spacers, such as the spacers 309a, required for the subsequent self-aligned nickel silicide formation. Then, an anneal cycle is performed for activating the dopant and curing crystal damage. Due to the implantation 340 carried out by using an implantation mask, i.e., the disposable spacers 309, recrystallizing the regions 331 may leave the corresponding extension region substantially without localized and clustered points and line defects so that the formation of any nickel silicide stingers may effectively be reduced.

It should be noted that the implantation for substantially amorphizing the active region 302, i.e., for forming the regions 331, may be carried out after performing an implantation for defining the extension regions as already described with reference to FIG. 3c.

In conclusion, the present invention allows one to significantly reduce or even substantially completely avoid the formation of the clustered point defects by amorphizing relevant portions in a crystalline semiconductor region prior to the formation of a metal silicide, such as a nickel silicide. Thus, the formation of metal silicide stingers, which significantly reduce production yield, may be remarkably restricted in that the crystalline structure in the relevant semiconductor regions is more efficiently re-established while meeting the restrictive thermal budget requirements necessary in highly sophisticated circuit elements, such as P-channel transistors and/or N-channel transistors with a critical dimension of 0.2 micrometers and less.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a metal silicide region in a doped silicon-containing semiconductor region, the method comprising:
implanting inert ions into said silicon-containing semiconductor region to substantially amorphize a portion thereof;
doping, at least partially, said substantially amorphous portion of the silicon-containing semiconductor region;
heat treating a substrate including said silicon-containing semiconductor region to substantially recrystallize said substantially amorphous portion;
depositing a refractory metal on a part of said silicon-containing semiconductor region; and
heating said substrate to initiate the metal silicide formation, wherein an intensified metal diffusion caused by crystal damage is reduced.

2. The method of claim 1, wherein said metal comprises nickel.

3. The method of claim 1, wherein implanting said inert ions is performed prior to doping said portion.

4. The method of claim 1, wherein doping, at least partially, said portion includes performing a first implantation of ions of a first conductivity type, forming a mask element to protect a specified portion of said silicon-containing semiconductor region, and performing a second implantation with ions of the first conductivity type into unmasked regions of the silicon-containing semiconductor region, wherein at least one of an implantation dose and energy differs in the first implantation from that of the second implantation.

5. The method of claim 1, wherein doping, at least partially, said portion includes forming a mask element to protect a specified region of said portion, performing a first dopant implantation with a first dose and a first energy, removing said mask element and performing a second dopant implantation with a second dose and energy, wherein the first dose and the first energy, respectively, differ from the second dose and the second energy.

6. The method of claim 4, wherein implanting inert ions is carried out after the first implantation.

7. The method of claim 5, wherein implanting inert ions is carried out after removing said mask element.

8. The method of claim 1, wherein at least one implantation parameter for implanting said inert ions is controlled to adjust a depth of said substantially amorphized portion in correspondence with a depth of said metal silicide.

9. The method of claim 8, wherein said at least one implantation parameter is at least one of an implant dose, an implant energy, a duration and a temperature of said substrate.

10. The method of claim 8, wherein said doped silicon-containing semiconductor region is a portion of an active region of a field effect transistor.

11. The method of claim 10, wherein said at least one implantation parameter is controlled in conformity with a predefined design thermal budget for forming said field effect transistor.

12. A method of forming a nickel silicide layer in a doped silicon-containing semiconductor region, the method comprising:
implanting inert ions into said silicon-containing semiconductor region to substantially amorphize a portion thereof;
doping, at least partially, said substantially amorphous portion of said silicon-containing semiconductor region;
heat treating said substrate to substantially recrystallize said substantially amorphous portion;
depositing a nickel layer on a part of said silicon-containing semiconductor region; and
initiating a chemical reaction between nickel and silicon to form said nickel silicide layer, wherein an increased nickel silicide formation at clustered crystal defects in said portion is reduced.

13. The method of claim 12, wherein substantially amorphizing said portion includes implanting inert ions into said portion.

14. The method of claim 12, wherein amorphization is performed prior to implanting dopants into said silicon-containing semiconductor region.

15. The method of claim 12, wherein implanting dopants includes performing a first implantation of ions of a first conductivity type, forming a mask element to protect a specified portion of said silicon-containing semiconductor region and performing a second implantation with ions of the first conductivity type into unmasked regions of the silicon-containing semiconductor region, wherein at least one of an implantation dose and energy differs in the first implantation from that of the second implantation.

16. The method of claim 12, wherein implanting dopants includes forming a mask element to protect a specified region of said portion, performing a first dopant implantation with a first dose and a first energy, removing said mask element and performing a second dopant implantation with a second dose and energy, wherein the first dose and the first energy, respectively, differ from the second dose and the second energy.

17. The method of claim 16, wherein amorphization is carried out after the first dopant implantation.

18. The method of claim 17, wherein amorphization is carried out after removing said mask element.

19. The method of claim 13, wherein at least one implantation parameter for implanting said inert ions is controlled to adjust a depth of said substantially amorphized portion in correspondence with a depth of said metal silicide.

20. The method of claim 19, wherein said at least one implantation parameter is at least one of implant dose, implant energy, duration and temperature of said substrate.

21. The method of claim 19, wherein said doped silicon-containing semiconductor region is a portion of an active region of a field effect transistor.

22. The method of claim 21, wherein said at least one implantation parameter is controlled in conformity with a predefined design thermal budget for forming said field effect transistor.

23. A method of forming a field effect transistor, the method comprising:
providing a substrate having formed thereon a silicon-containing semiconductor region;
forming a gate insulation layer on said semiconductor region;
forming a gate electrode on said gate insulation layer;
forming source and drain regions including extension regions in said semiconductor region by implanting ions of a first conductivity type;
substantially amorphizing at least a portion of said semiconductor region;
recrystallizing said substantially amorphized portion; and
forming a nickel silicide region in a part of said source and drain regions.

24. The method of claim 23, wherein substantially amorphizing is carried out prior to forming source and drain regions.

25. The method of claim 23, wherein substantially amorphizing includes implanting inert ions.

26. The method of claim 25, wherein at least one implantation parameter is controlled during implanting said inert ions to adjust a depth of said portion.

27. The method of claim 26, wherein said depth of said portion is selected on the basis of a design depth of said nickel silicide region.

28. The method of claim 27, wherein said depth substantially coincides with said design depth of said nickel silicide region.

29. The method of claim 27, wherein said depth substantially is greater than said design depth of said nickel silicide region and less than a depth of said drain and source regions.

30. The method of claim 23, wherein substantially amorphizing a portion includes implanting inert ions with a tilt angle with respect to a direction normal to a surface of said substrate.

31. The method of claim 23, wherein said field effect transistor is formed on the basis of a design thermal budget defined for the formation process of the field effect transistor.
